(19) United States
(12) Patent Application Publication
(10) Pub. No.: US 2002/0165683 A1
(43) Pub. Date: Nov. 7, 2002

(54) Fast fourier transform apparatus

(75) Inventor: Jeong-Sang Lee, Seoul (KR)

Correspondence Address: SUGHRUE MION, PLLC, 2100 Pennsylvania Avenue, NW, Washington, DC, 20037-3213, US

(73) Assignee: SAMSUNG ELECTRONICS CO., LTD.

(21) Appl. No.: 10/101,743

(22) Filed: Mar. 21, 2002

(30) Foreign Application Priority Data
Apr. 17, 2001 (KR) 2001-20552

(51) Int. Cl. G01R 23/16

(52) U.S. Cl. 702/77

(57) ABSTRACT

A fast fourier transform apparatus is disclosed having a simple processing structure and improved processing speed. The fast fourier transform apparatus includes a memory and an operation processing portion that classifies to-be-processed data stored in the memory into data processing groups, according to a priority value given to the plurality of radix operators based on the amount of bit processing per unit. The memory is controlled so that the to-be-processed data is processed by the radix-operators in accordance with the order of the classified data processing. An order of the classified data processing groups processed by the radix operators is recovered by re-arranging the data processing groups according to a reversing method which corresponds to the operation processing order. The radix operations and data recovery is performed by reversing the digits just one time, thereby simplifying the procedure of the operation.

### BACKGROUND OF THE INVENTION

1. Field of the Invention

The present invention relates to a fast fourier transform (FFT) apparatus.

2. Description of the Related Art

Broadcasting methods are being transferred from analog communications to digital communications in accordance with recent developments in digital technology. Radio broadcasting companies have already started digital broadcasting service or are preparing for digital broadcasting service. The Orthogonal Frequency Division Multiplex (OFDM) is adopted for transmitting data in the digital audio broadcasting (DAB) format. The OFDM uses the fast fourier transform (FFT) and can process a Forward FFT of various inputs. Also, the OFDM can process an Inverse FFT in accordance with a design of a synchronization portion in a total system.

The FFT is one of the most significant algorithms utilized in a field of digital signal processing (DSP), and is also the general name of an algorithm for building the discrete fourier transform (DFT). The algorithm for the FFT is formed by at least one integrated circuit that processes a signal in real time. The FFT operation is performed using software that is implemented in a programmable digital signal processor (DSP) or a dedicated FFT processor. (N) Points direct DFT is expressed by the following equations.

$$X ( k ) = {\sum }_{i = 0}^{n - 1} x ( n ) {W}_{N}^{nk} \qquad [ Equation 1 ]$$

where, k is 0, 1, 2 . . . , N−1.

$${W}_{N}^{nk} = {ⅇ}^{- j ( 2 π ) nk / N} \qquad [ Equation 2 ]$$

where,

$${W}_{N}^{nk}$$

is a twiddle factor.

FIG. 1 shows a basic structure of a radix-2 butterfly portion representing the expression of equation 1. The relation between input and output is expressed by the following equation.

$$X [ k ] = x [ n ] + x [ n + N / 2 ] {W}_{N}^{k} \\ X [ k + N / 2 ] = x [ n ] - x [ n + N / 2 ] {W}_{N}^{k} \qquad [ Equation 3 ]$$

FIG. 2 is a diagram showing a signal flow in a 16-point radix-2 FFT processor. The butterfly operation of the 16-point FFT is performed by four butterfly stages (I, II, III, IV), each of which is has eight butterfly portions.

FIG. 3 is a diagram showing a signal flow of a radix-4 butterfly portion representing the expression of equation 1. FIG. 4 is a diagram showing a signal flow in a 16-point radix-4 FFT processor. The 16-point FFT butterfly operation is performed using two butterfly stages, each of which has four butterfly portions.

The radix-2 can process any inputs that are comprised of 2ⁿ bits such as 256, 512, 1024, 2048, but has a shortcoming in that the radix-2 process is relatively slow. The radix-4 can process any inputs that are comprised of 4ⁿ bits such as 256, 1024, but has a shortcoming in that the radix-4 cannot process the inputs of 512, 2048, etc., since these are not in the form of 4ⁿ bits. Accordingly, in consideration of these points, it is preferable to combine the structures of radix-2 and radix-4 with each other.

FIG. 5 is a block diagram schematically showing a conventional fast fourier transform apparatus.

Referring to FIG. 5, the FFT apparatus comprises an address generator 100, a first RAM 200, a user programmable DSP 300, and a second RAM 400.

The address generator 100 and the user programmable DSP 300 receive the to-be-processed data. The address generator 100 generates an address with respect to the to-be-processed data and is connected to the first RAM 200 to transmit the generated address to the first RAM 200. The first RAM 200 receives the address generated from the address generator 100 and also receives the to-be-processed data from the user programmable DSP 300. Then, the first RAM 200 re-arranges the to-be-processed data received from the user programmable DSP 300 in accordance with the address received from the address generator 100.

The user programmable DSP 300 receives address data from the first RAM 200 and processes the received address data by an operation. The user programmable DSP 300 is connected to the second RAM 400 to transmit the data processed by the operation to the second RAM 400. The second RAM 400 receives the data processed by the operation of the user programmable DSP 300 and stores the same therein.

FIG. 6 is a view illustrating the address generator 100 of FIG. 5.

Referring to FIG. 6, the address generator 100 comprises a user program register 115, a reverse sequence address generator 120, and a non-reverse digit controller 135.

The user program register 115 provides the reverse sequence address generator 120 with a binary code signal representing the to-be-processed data. The binary code signal, which is provided by the user program register 115, may be expressed by N/2, where N is obtained by serially multiplying all the radixes in the butterfly operation performed at the user program DSP 300.

The reverse sequence address generator 120 reverses a sequence of bits for the input data received from the user program register 115 in a manner that a most significant bit (MSB) of the input data is transferred to a least significant bit (LSB) position, and vice versa, and then outputs the reversed data. Intermediate bits of the input data, which are between the MSB and the LSB, are also re-arranged by the reverse sequence address generator 120. Accordingly, the reverse sequence address generator 120 reverses a sequence of the binary code signal received from the user program register 115.

The non-reversing digit controller 135 controls a number of switches corresponding to the number of bits of data outputted from the reverse sequence address generator 120. For example, if the data outputted from the reverse sequence address generator 120 has 20 bits, the non-reversing digit controller 135 controls 20 switches.

Other address sequence generator 110 is the so-called butterfly weighted sequence that provides a predetermined twiddle factor W(k) to the user programmable DSP 300 (refer to FIG. 5).

For example, if N=32, the binary code signals such as 000010 . . . 000, 000100 . . . 000, 000110 . . . 000, 001000 . . . 000, . . . , 111110 . . . 000, etc., are transmitted from the user program register 115 to the reverse sequence address generator 120. In the above example, the reverse sequence address generator 120 reverses a sequence of each binary code signal received from the user program register 115 such as 000 . . . 010000, 000 . . . 001000, 000 . . . 011000, 000 . . . 000100, . . . , 000 . . . 011111, etc., and then outputs the reversed sequence address data through a output bus 131.

If the inputted address data has 20 bits, the output bus 131 of the reverse sequence address generator 120 outputs from lines of E₀₀ through E₁₉. Here, the LSB of the output bus 131 is transmitted through the line of E₀₀ and the MSB of the output bus 131 is transmitted through the line of E₁₉.

There are switches (SW₀, SW₁, SW₂, . . . , SW₁₉) arranged in number to correspond to the number of lines of E₀₀ through E₁₉. The non-reversing digit controller 135 selects one of the switches (SWⱼ) and does not allow bits transmitted through the selected switch to be reversed. As a result, the address generator 100 transmits the address generated from the reverse sequence generator 120 to the first RAM 200 and non-reverses a sequence of the bits selected by the non-reversing digit controller 135.

The first RAM 200 receives the address data from the address generator 100 and stores the same therein. The user programmable DSP 300 receives the address data stored in the first RAM 200 and then performs the butterfly operation with respect to the received address data by a program stored therein. At this time, during the butterfly operation, the bits selected by the non-reversing digit controller 135 maintain their original sequence without being non-reversed.

FIG. 7 shows an example of reversing digits in 32-point for FIG. 5.

When the conventional FFT apparatus performs 32-point radix 4-4-2, at a first stage, the reverse sequence address generator 120 (refer to FIG. 6) reverses the sequence as described above. For example, at the first stage, the address data is initially arranged as a4 a3 a2 a1 a0 and is re-arranged to a0 a1 a2 a3 a4 by reversing the sequence thereof. Then, at a second stage, the user programmable DSP 300 performs the butterfly operation with respect to the reverse sequence address. At this time, the non-reversing digit controller 135 (refer to FIG. 6) selects a bit and does not allow the bit to be reversed. In the above example of radix 4-4-2, a0 a1 and a2 a3 are respectively re-arranged by reversing the digits, but a4 maintains its original position.

According to the conventional FFT apparatus, the address generator is operated by two stages, a first of which is to reverse the sequence of the data, and a second of which is to reverse the digits of the reversed sequence address by the user programmable DSP 300, except for bits selected by the non-reversing digit controller 135. Also, the conventional FFT apparatus must include extra sophisticated logic in the non-reversing digit controller 135 according to the radix structure in each stage. The sophisticated logic is required more when the radix-2 is processed first or intermediately in the mixed structure of radix-4 and radix-2.

### SUMMARY OF THE INVENTION

The present invention is developed in order to solve the above problem, and an object of the present invention is to provide a fast fourier transform apparatus which has a simple processing structure and can improve a processing speed.

In order to achieve the above object, a fast fourier transform apparatus according to the present invention, which performs a butterfly operation with a plurality of radix operators that are different from each other in amount of bit processing per unit, includes a memory, and an operation processing portion that classifies to-be-processed data stored in the memory into data processing groups according to a priority given to the plurality of radix operators by an order of the amount of bit processing per unit. The memory is controlled in a manner that the to-be-processed data is processed by the radix-operators corresponding to the classified data processing groups by the order of the classified data processing, respectively, and for recovering the classified data processing groups processed by the radix operators and stored in the memory by re-arranging according to a reversing method which corresponds to the operation processing order.

Preferably, the operation processing portion comprises a butterfly operation address generator for generating an operation address corresponding to each data processing group from a processing attribute information with respect to the to-be-processed data stored in the memory, a reverse digit address generator for generating a reversed digit address to recover an arrangement of the data processed by the radix operators according to the processing attribute information and stored in the memory, a first switching portion for selecting the operation address or the reversed digit address according to a first switching control signal, and outputting the selected address to the memory. A second switching portion is provided for selectively connecting the memory to one of the radix operators according to a second switching control signal, and a FFT controller is provided for analyzing the to-be-processed data, for generating and outputting the processing attribute information for the butterfly operation according to the analyzed result and for recovering the arrangement of the data. The FFT controller outputs the first switching control signal and the second switching control signal according to the processing attribute information.

The processing attribute information comprises a stage counter value that is sequentially given by a processing order of the classified data processing groups of the to-be-processed data, and the number of total stages.

The radix operators include a radix-4 operator and a radix-2 operator, and if the stage counter value is greater than the number of total stages, the FFT controller controls the first switching portion to output the reversed digit address to the memory.

The radix operators comprise a radix-4 operator and a radix-2 operator, and if the number of total bits of the to-be-processed data is odd and the stage counter value is equal to the number of total stages, the FFT controller controls the second switching portion to connect the memory to the radix-2 operator.

Accordingly, since the operation is completed by reversing the digits just one time, the operation processing and recovering procedure is simplified.

### BRIEF DESCRIPTION OF THE DRAWINGS

The above object and characteristic of the present invention will be more apparent from the following detailed description of the preferred embodiments of the present invention in conjunction with the accompanying drawings, in which:

FIG. 1 is a diagram showing a signal flow for expressing an equation regarding a discrete fourier transform by a radix-2 butterfly portion;

FIG. 2 is a diagram showing a signal flow in a 16-point radix-2 FFT processor;

FIG. 3 is a diagram showing a signal flow for expressing an equation regarding a discrete fourier transform by a radix-4 butterfly portion;

FIG. 4 is a diagram showing a signal flow in a 16-point radix-4 FFT processor;

FIG. 5 is a schematic block diagram showing a conventional fast fourier transform (FFT) apparatus;

FIG. 6 is a schematic diagram showing the address generator of FIG. 5;

FIG. 7 illustrates an example of reversing a digit in a 32-point FFT value by the apparatus of FIG. 5;

FIG. 8 illustrates a block diagram of a fast fourier transform apparatus according to a preferred embodiment of the present invention;

FIG. 9 illustrates a reverse digit address generator of FIG. 8;

FIG. 10 illustrates an example of reversing a digit transformed according to the FFT value by the FFT apparatus of FIG. 8; and

FIG. 11 illustrates an example of reversing a digit in a 32-point FFT value by the FFT apparatus of FIG. 8;

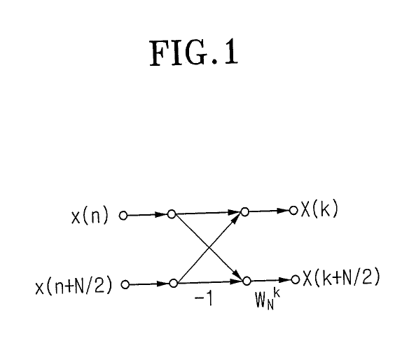

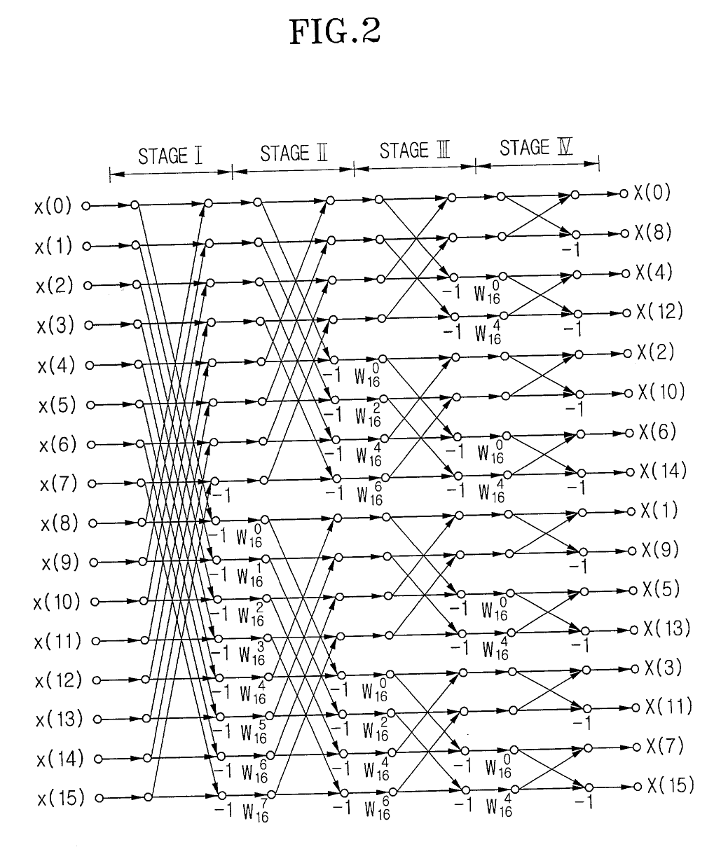

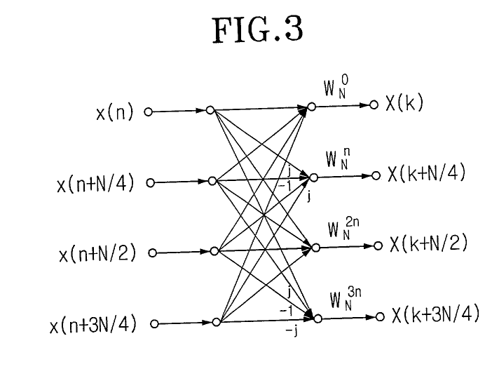

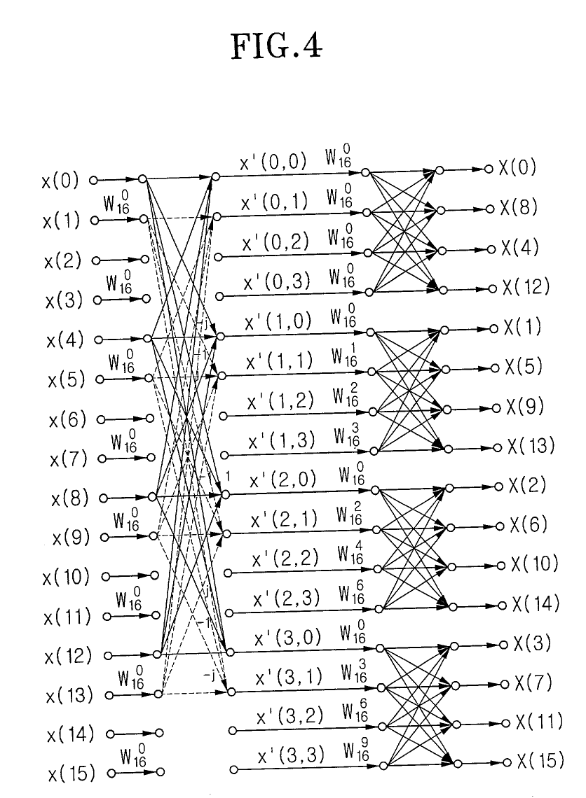

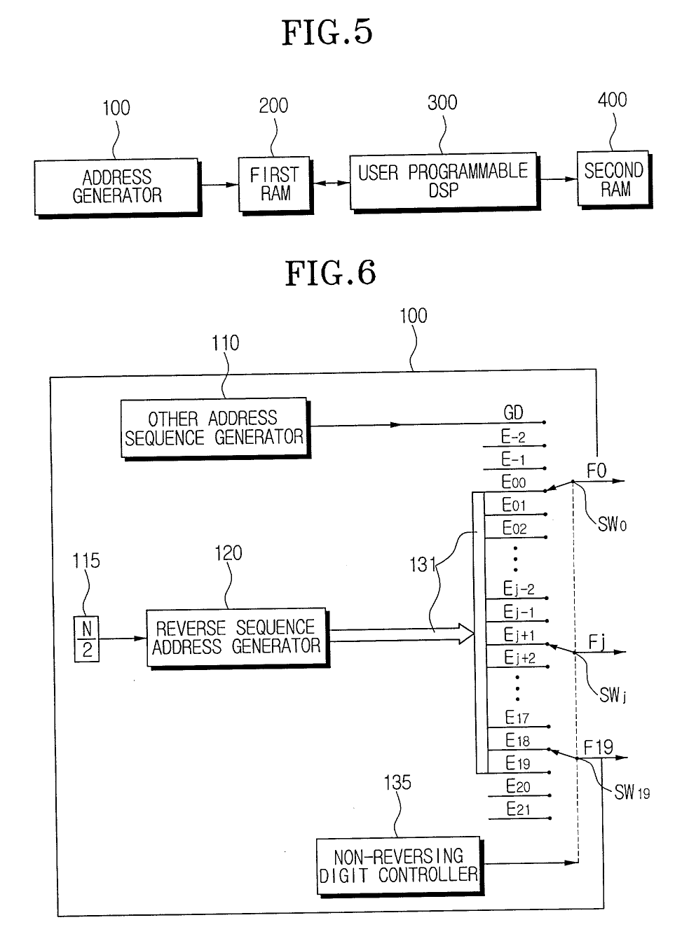

Hereinafter, the present invention will be described in greater detail with reference to the accompanying drawings.

### DETAILED DESCRIPTION OF THE PREFERRED EMBODIMENT

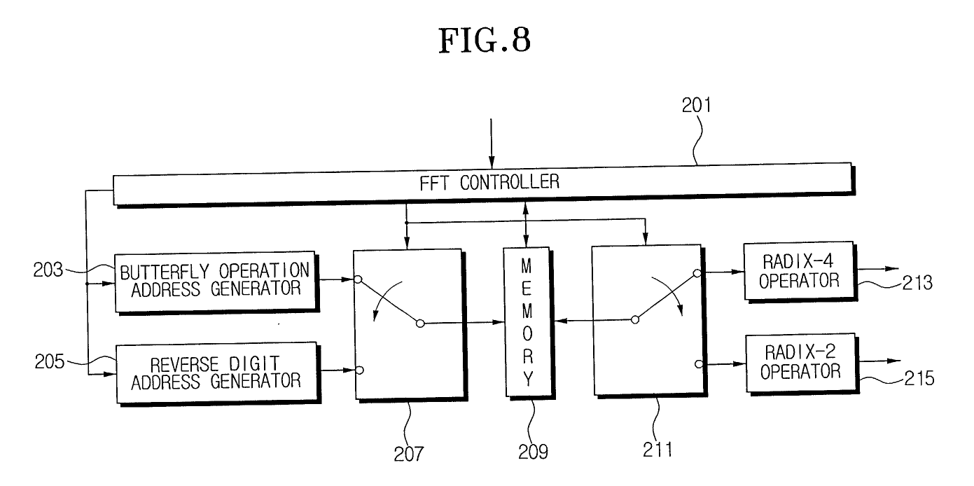

FIG. 8 illustrates a preferred embodiment of a fast fourier transform apparatus according to the present invention.

Referring to FIG. 8, the fast fourier transform (FFT) apparatus includes an FFT controller 201, a butterfly operation address generator 203, a reverse digit address generator 205, a first multiplex 207, a memory 209, a second multiplex 211, a radix-4 operator 213, and a radix-2 operator 215.

The FFT controller 201 controls the above-mentioned elements for a butterfly operation of to-be-processed data and recovers an arrangement of the operated data. The FFT controller 201 generates processing attribute information in number corresponding to the number of total bits of the to-be-processed data, the processing attribute information being required to control the above elements. The FFT controller 201 stores the inputted data, to be processed data by the FFT, in the memory 209.

The FFT controller 201 classifies the to-be-processed data stored in the memory 209 into data processing groups and determines a processing order with respect to the classified data processing groups in a way that gives priority to data processing group to be processed by the radix operator that processes relatively greater amount of bits per unit, while giving a last order to a data processing group to be processed by a radix operator which processes relatively less amount of bits per unit. The order of data processing groups is determined in a manner that the to-be-processed data is grouped by bits in the number corresponding to the radix operator processing relatively greater amount of bits per unit, starting from the LSB.

The FFT controller 201 controls the butterfly operation address generator 203, the first multiplex 207, the memory 209, and the second multiplex 211 to process the classified data processing group by the corresponding radix operator. Also, the FFT controller 201 controls the memory 209 via the reverse digit address generator 205 and the first multiplex 207 to recover the data processed by the radix operators 213 and 215, which is stored in the memory 209, by reversing digits of the data in accordance with the processing order of the data processing groups.

If the radix-4 operator 213 and the radix-2 operator 215 are employed as shown in FIG. 8, the FFT controller 201 determines the order of the data processing groups by classifying the to-be-processed data into groups by two digits, starting from the LSB. Here, the order of data processing groups corresponds to a stage counter value (to be described later).

If a data processing group includes 2 bits, which is determined in accordance with the order of the data processing groups, the FFT controller 201 controls the above respective elements to process the data processing group of 2 bits by the radix-4 operator. Also, if the data processing group of the last order is comprised of 1 bit, the FFT controller 201 controls the above respective elements to process the data processing group of 1 bit by the radix-2 operator. If the respective data processing groups are completely processed by the respective radix operators, the FFT controller 201 controls the respective elements to recover the arrangement of the data processed by the reversed digit address in accordance with the processing order of the data processing groups.

The processing attribute information for the to-be-processed data includes a stage counter value for a data processing group, a number of total stages, a binary counter value, and log₂(FFT value).

The butterfly operation address generator 203 receives the processing attribute information concerning the to-be-processed data, including the stage counter value and the number of total stages from the FFT controller 201 and then generates the butterfly operation address with respect to the to-be-processed data in accordance with the received processing attribute information.

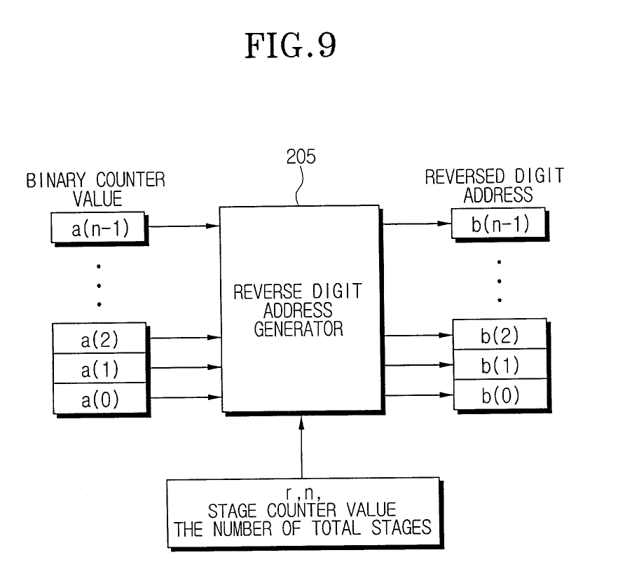

The reverse digit address generator 205, as shown in FIG. 9, generates the reversed digit address in accordance with the processing attribute information including the stage counter value, the number of total stages, the binary counter value, and log₂(the FFT value) with respect to the to-be-processed data by the FFT and received from the FFT controller 201.

Being employed as a first switching portion, the first multiplex 207 is connected to the FFT controller 201 and memory 209. The first multiplex 207 is controlled by the FFT controller 201 to output the address generated from the butterfly operation address generator 203 to the memory 209, during the butterfly operation of the to-be-processed data, and to output the address generated from the reverse digit address generator 205 to the memory 209 after the operation of the radix operators 213 and 215.

Preferably, if a current stage counter value of the to-be-processed data is less than or equal to the number of total stages, the first multiplex 207 connects to the butterfly operation address generator 203. Also, if a stage counter value of the to-be-processed data is greater than the number of total stages, the first multiplex 207 connects to the reverse digit address generator 205.

During the operation of the radix operators 213 and 215, the memory 209 outputs data corresponding to the address received from the first multiplex 207 through the second multiplex 211.

The memory 209 re-arranges the data processed in accordance with the address received from the first multiplex 207 after the operation of the radix operators 213 and 215.

Being employed as a second switching portion, the second multiplex 211 is controlled by the FFT controller 201 to selectively connect the memory 209 to one of the radix operators 213 and 215. If the number of total bits of the to-be-processed data is even, the second multiplex 211 is controlled by the FFT controller 201 to connect the memory 209 to the radix-4 operator 213 until the stage counter value reaches total stages.

If the number of total bits of the to-be-processed data is odd, before the stage counter value reaches the total stages, the second multiplex 211 is controlled by the FFT controller 201 to connect the memory 209 to the radix-4 operator 213, but when the stage counter value reaches to the total stages, the second multiplex 211 is controlled by the FFT controller 201 to connect the memory 209 to the radix-2 operator 215. The second multiplex 211 receives the processing attribute information including the stage counter value, the number of total stages, and the value of “r” with respect to the to-be processed data from the FFT controller 201 to perform a switching control function. Here, the value of “r” is [log₂(FFT value=N)]MOD 2. Also, the [log₂(FFT value=N)]MOD 2 results in a remainder when log₂(FFT value) is divided by two. If the remainder is 0, the second multiplex 211 is controlled so that the to-be-processed data is only processed by the radix-4 operator 213, and if the remainder is not 0, the second multiplex 211 is controlled so that the to-be-processed data is processed by the radix-2 generator 215 when the stage counter value reaches the total stages.

The radix-4 and the radix-2 operators 213 and 215 process the data which is received from the memory 209 through the second multiplex 211 by the butterfly operation and then store the data in the corresponding address.

The operation of the fast fourier transform apparatus is described as follows.

The FFT controller 201 receives the to-be-processed data and then stores the data in memory 209. The FFT controller 201 analyzes the to-be-processed data and outputs the number of total stages, the stage counter value, the FFT value, the log₂(FFT value), the binary counter value, and the value of “r”, etc. The number of total stages is determined by dividing the to-be-processed data into units of 2 digits, which includes a unit of 1 digit. For example, if the to-be-processed data expressed by a binary number comprises 5 bits such as a4 a3 a2 a1 a0, the data is divided into 3 stages such as (a1 a0), (a3 a2), (a4) according to the aforementioned dividing method. Here, the FFT value is 32 which results from a combination of possible numbers with respect to 5 binary codes i.e. 4×4×2=32, and thus log₂(FFT vale)=log₂32=5. The binary counter value is determined by counting each binary number starting from a left binary number to a right binary number of the to-be-processed data. The value of “r” is 1 results from the equation of [log₂(FFT value)]MOD 2=[log₂32]MOD 2=1.

The FFT controller 201 provides the analyzed processing attribute information, including the stage counter value, the number of total stages, and the value of “r” with respect to the to-be-processed data, to the butterfly operation address generator 203.

The butterfly operation address generator 203 generates the operation address corresponding to the processing attribute information received from the FFT controller 201. In the example of the to-be-processed data as described above, the number of total stages is 3, the FFT value is 32, and the value of “r” is 1. Thus, the butterfly operation address generator 203 sequentially generates an address in accordance with the stage counter value to perform the radix-4 operation two times and the radix-2 operation one time. That is, the butterfly operation address generator 203 generates an address in accordance with the stage counter value received from the FFT controller 201 such as an address for the radix-4 operation at the stage counter value of 1, an address for the radix-4 operation at the stage counter value of 2, and an address for the radix-2 operation at the stage counter value of 3. When the to-be-processed data is a4 a3 a2 a1 a0 as in the above example, if the butterfly operation address generator 203 receives a stage counter value of 1 from the FFT controller 201, the butterfly operation address generator 203 generates an address to process the data of a1 a0 by the radix-4 operator 213. Next, if the butterfly operation address generator 203 receives a stage counter value of 2 from the FFT controller 201, the butterfly operation address generator 203 generates an address to process the data of a3 a2 by the radix-4 operator 213. Further, if the butterfly operation address generator 203 receives a counter value of 3 from the FFT controller 201, the butterfly operation address generator 203 generates an address to process the data of a4 by the radix-2 operator 215.

While the stage counter value reaches 3, the first multiplex 207 transmits the addresses received from the butterfly operation address generator 203 to the memory 209. Then, among the data stored in the memory 209, the data which corresponds to the addresses generated from the butterfly operation address generator 203 is processed by the radix operators 213 and 215.

The second multiplex 211 compares the number of total stages with the stage counter value for the data received from the FFT controller 201. At this time, if a stage counter value is equal to the number of total stages and r=[log₂(FFT value)]MOD 2=1, the second multiplex 211 is switched from the radix-4 operator 213 to the radix-2 operator 215. In the above example, the number of total stages is 3, FFT value is 32, and thus r=[log₂(32) MOD 2]=1. Accordingly, if the stage counter value is 1, the second multiplex 211 transmits the data received from the memory 209 to the radix-4 operator 213, and if the stage counter value is 2, the second multiplex 211 transmits the data received from the memory 209 to the radix-4 operator 213. If the stage counter value is 3, which is equal to the number of total stages, and also the value of “r” is 1, then the second multiplex 211 connects the memory 209 to the radix-2 operator 215.

Meanwhile, while the data is processed in the respective stages by the respective corresponding radix operators 213 and 215, the reverse digit address generator 205 generates the reversed digit address from the processing attribute information.

Also, the first multiplex 207 compares the stage counter value received from the FFT controller 201 with the number of total stages. If the stage counter value is greater than the number of total stages, the first multiplex 207 cuts a switch connection with the butterfly operation address generator 203 and then switch connects to the reverse digit address generator 205. When the to-be-processed data is a4 a3 a2 a1 a0 as in the above example, in which the number of total stages is 3, if the counter value is 4, the first multiplex 207 is switch connected from the butterfly operation address generator 203 to the reverse digit address generator 205.

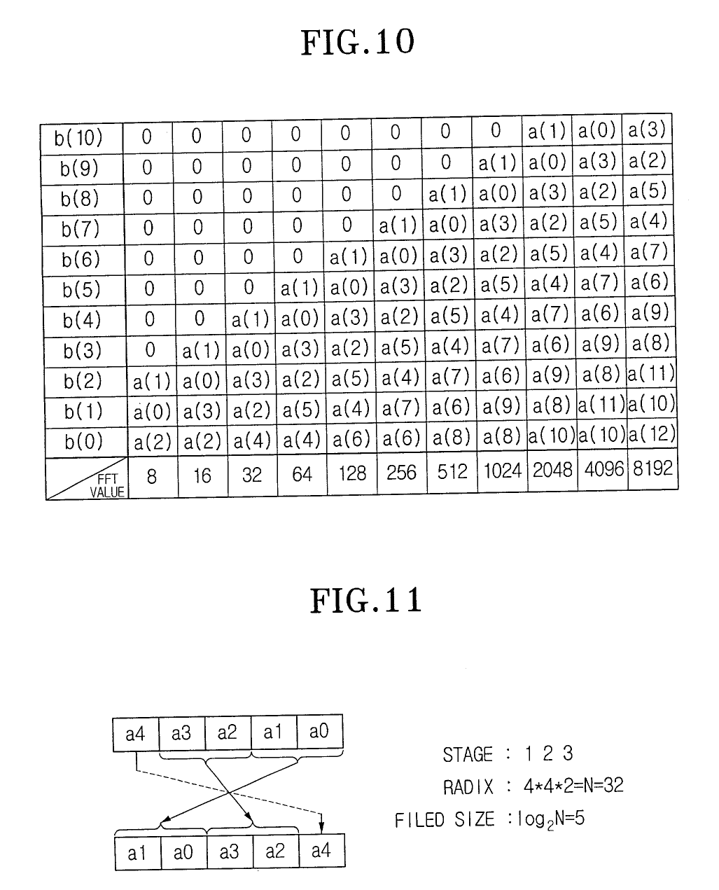

The reverse digit address generator 205 outputs the reversed digit address, which is generated all over the total stages in accordance with the processing attribute information including the number of total stages, the stage counter value, the binary counter value, and the value of “r” with respect to the to-be-processed data, through the first multiplex 207. If the to-be-processed data includes more than 3 bits, the reverse digit address generators 205 generates the reversed digit address in a manner that the rightmost two bits are transferred to the leftmost two bits thereby unreversing, and the leftmost one or two bits is transferred to the rightmost one or two bits thereby un-reversing. FIG. 10 shows the re-arrangement of the data according to the reversed digit address that is generated from the reverse digit address generator 205 of FIG. 9, according to the number of total bits of the to-be-processed data.

As shown in FIG. 10, if the to-be-processed data is stored in the memory 209 with a sequence of a4 a3 a2 a1 a0, the data is re-arranged to a sequence of a1 a0 a3 a2 a4 in accordance with the reversed digit address.

Also, referring to FIG. 10, it is noticed that there is a series of rules depending on the FFT value. That is, if the FFT value is 2²ⁿ, the data is only processed by the radix-4 operator, and if the FFT value is 2²ⁿ⁺¹, the data is processed by the radix-4 operator “n” times and the radix-2 operator one time. Here, if the FFT value is 2 or 4, there is no need to reverse the digit, thus the illustration thereof has been omitted.

FIG. 11 shows an example of reversing the digit by the FFT apparatus of FIG. 8 when the FFT value is 32-point.

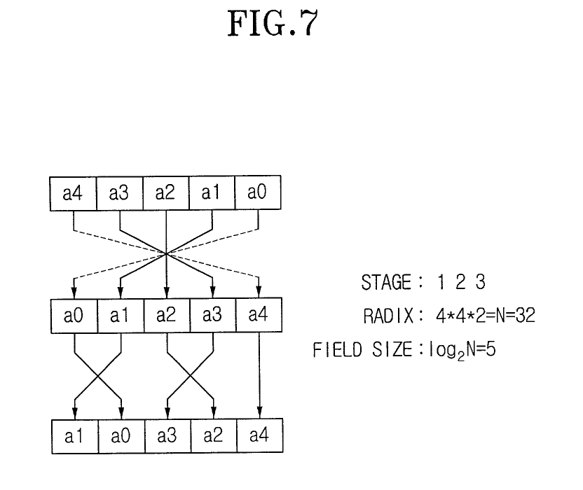

Referring to FIG. 11, when the FFT value is 32-point, the FFT apparatus reverses the digit with the data being stored in the butterfly operation address. It goes without saying that the structure of the reversed digit address is identical to the conventional structure (refer to FIG. 7).

According to another aspect of the present invention, as shown in FIG. 10, there is provided a sub-memory storing the reversed digit address data. At this time, if the to-be-processed data is input, the FFT controller 201 searches the reversed digit address, which corresponds to the processing attribute information resulted by analyzing the to-be processed data, from the sub-memory and then outputs the reversed digit address through the memory 209.

According to the present invention, due to the mixed structure of the radix-4 and the radix-2 operators, the FFT apparatus performs first the radix-4 operation and then performs the radix-2 operation according to the FFT value of the to-be-processed data. Accordingly, since the operation is completed by reversing the digits just one time, the operation processing and recovery procedure can be simplified.

Although preferred embodiments of the present invention have been shown and described, it will be appreciated by those skilled in the art that changes may be made to these embodiments without departing from the principles and spirit of the invention, the scope of which is defined in the claims and their equivalents.

What is claimed is:

1. A fast fourier transform apparatus for performing a butterfly operation, comprising:
a plurality of radix operators that are different from each other in an amount of bit processing per unit;
a memory; and
operation processing means for classifying to-be-processed data that is stored in the memory into data processing groups according to an order of priority given to the plurality of radix operators, wherein the priority order is determined by the bit processing amount per unit, wherein the operation processing means further controls the memory in a manner that the to-be-processed data is processed by the radix-operators according to the order of the classified data processing groups, respectively, and wherein the operation processing means recovers the classified data processing groups that are processed by the radix operators for storage in the memory by re-arranging the processed data order according to a reversing method that corresponds to the order of the classified data processing groups.

2. The fast fourier transform apparatus of claim 1, wherein the operation processing means comprises:
a butterfly operation address generator that receives process attribute information for the to-be-processed data corresponding to each data processing group and generates an operation address with respect to the to-be-processed data in accordance with the process attribute information;
a reverse digit address generator that generates a reversed digit address to recover an arrangement of the data, processed by the radix operators and stored in the memory, according to the processing attribute information;
a first switching portion that selects the operation address or the reversed digit address according to a first switching control signal, and outputs the selected address to the memory;
a second switching portion that selectively connects the memory to one of the radix operators according to a second switching control signal; and
an FFT controller that receives and analyzes the to-be-processed data to generate and output the processing attribute information for the butterfly operation according to the analyzed result, the FFT controller being adapted to recover the data arrangement and output the first switching control signal, and the second switching control signal, according to the processing attribute information.

3. The fast fourier transform apparatus of claim 2, wherein the processing attribute information comprises:
a stage counter value that is sequentially given by a processing order of the classified data processing groups for the to-be-processed data; and
a total stage value representing a number of total stages.

4. The fast fourier transform apparatus of claim 3, wherein the radix operators comprise a radix-4 operator and a radix-2 operator, and wherein if the stage counter value is greater than the total stage value, the FFT controller is adapted to control the first switching portion to output the reversed digit address to the memory.

5. The fast fourier transform apparatus of claim 3, wherein the radix operators comprise a radix-4 operator and a radix-2 operator, and wherein if a number of total bits of the to-be-processed data is odd and the stage counter value is equal to the total stage value, the FFT controller is adapted to select the second switching portion to connect the memory to the radix-2 operator.

6. A fast fourier transforming apparatus performing a butterfly operation comprising:
a radix-4 operator;
a radix-2 operator; and
operation processing means for classifying to-be-processed data that is stored in a memory into unit processing groups by grouping 2 digits starting from a LSB and determining an order of the processing groups, the operation processing means further processes a processing group of 2 digits with the radix-4 operator in accordance with the determined order for the processing groups and processes a processing group of 1 digit in last order with the radix-2 operator, and reverses the digits according to the operation processing order to recover an arrangement of total data processed by the radix operators.

7. The fast fourier transforming apparatus of claim 6, wherein the operation processing means re-arranges the processing groups, which are classified by the determined order starting from the LSB of the to-be-processed data, to a different order starting at a MSB position while maintaining an original order of bits within the respective processing groups.

8. A fast fourier transform apparatus for performing a butterfly operation, comprising:
a plurality of radix operators having different bit processing rates per unit;
a memory;
an FFT controller having an input that receives to-be-processed data, the FFT controller being adapted to classify the to-be-processed data into data processing groups and output processing attribute information;
a butterfly operation address generator that is connected to the FFT controller and receives the process attribute information corresponding to the data processing groups, the butterfly operation address generator being adapted to generate an operation address for the to-be-processed data in accordance with the process attribute information;
a reverse digit address generator that is connected to the FFT controller and generates a reversed digit address to recover an arrangement of the data processed by the radix operators according to the processing attribute information;
a first switching portion adapted to select the butterfly operation address generator or the reversed digit address generator according to a first switching control signal, and provide an output to the memory; and
a second switching portion adapted to selectively connect the memory to one of the radix operators according to a second switching control signal,
wherein the FFT controller is adapted to recover the data arrangement and output the first switching control signal and the second switching control signal according to the processing attribute information.

9. The fast fourier transform apparatus of claim 8, wherein the processing attribute information comprises:
a stage counter value that is sequentially given by a processing order of the classified data processing groups for the to-be-processed data; and
a total stage value representing a number of total stages.

10. The fast fourier transform apparatus of claim 9, wherein the radix operators comprise a radix-4 operator and a radix-2 operator, and wherein if the stage counter value is greater than the total stage value, the FFT controller is adapted to control the first switching portion to output the reversed digit address to the memory.

11. The fast fourier transform apparatus of claim 10, wherein the radix operators comprise a radix-4 operator and a radix-2 operator, and wherein if a number of total bits of the to-be-processed data is odd and the stage counter value is equal to the total stage value, the FFT controller is adapted to select the second switching portion to connect the memory to the radix-2 operator.
